(19) United States
(12) Patent Application Publication
(10) Pub. No.: US 2008/0305574 A1
(43) Pub. Date: Dec. 11, 2008

(54) METHOD OF MANUFACTURING NONVOLATILE MEMORY DEVICE USING CONDUCTIVE ORGANIC POLYMER HAVING NANOCRYSTALS EMBEDDED THEREIN

(75) Inventors: Jea-Gun Park, Gyeonggi-do (KR); Gon-Sub Lee, Seoul (KR); Byeong-Il Han, Busan (KR); Jong-Dae Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/108,612

(22) Filed: Apr. 24, 2008

(30) Foreign Application Priority Data
Apr. 25, 2007 (KR) 10-2007-0040520
Apr. 25, 2007 (KR) 10-2007-0040521

(51) Int. Cl. H01L 51/30

(52) U.S. Cl. 438/99; 257/E51.035; 257/E21.159

(57) ABSTRACT

The method of manufacturing a nonvolatile memory device includes forming a lower conductive layer on a substrate; forming a first conductive organic layer on the substrate using spin coating; forming a metal layer for forming nanocrystals on the first conductive organic layer, the metal layer partially overlapping the first conductive organic layer; forming a second conductive organic layer on the first conductive organic layer using spin coating; transforming the metal layer into nanocrystals by curing; and forming an upper conductive layer on the second conductive organic layer, the upper conductive layer partially overlapping the nanocrystals. The conductive organic polymer may be poly-N-vinylcarbazole (PVK) or polystyrene (PS).

### CROSS-REFERENCE TO RELATED APPLICATION

This application claims priority from Korean Patent Application Nos. 10-2007-0040521 and 10-2007-0040520 each filed on Apr. 25, 2007 in the Korean Intellectual Property Office, the disclosures of which are incorporated herein by reference in their entireties.

### BACKGROUND OF THE INVENTION

The present invention relates to a nonvolatile memory device and a method of manufacturing the nonvolatile memory device, and more particularly, to a nonvolatile memory device using a conductive organic material having metallic nanocrystals that can provide two different conductive states at the same voltage, and a method of manufacturing the nonvolatile memory device.

Memory devices are largely classified into volatile memory devices such as dynamic random access memory (DRAM) devices and nonvolatile memory devices such as flash memory devices.

A DRAM forms a channel between source and drain terminals by adjusting the channel width under a gate in response to a voltage applied to the gate, and charges or discharges a capacitor connected thereto. Thereafter, the DRAM classifies the charge or discharge state of the capacitor as a data value of 0 or 1. However, a DRAM needs to continuously charge a capacitor and generally consumes a considerable amount of power because of a high probability of data loss caused by a leakage current.

A flash memory often causes Fowler-Nordheim (F-N) tunneling in response to a voltage applied to a control gate and a channel region, varies the amount of charge in a floating gate, and measures the threshold voltage of a channel. Then, the flash memory classifies the threshold voltage of the channel as a data value of 0 or 1. However, a flash memory may cause a considerable increase in voltage used therein due to the use of F-N tunneling. Further, the data processing speed of a flash memory is generally low since a flash memory reads or writes data in a predetermined order.

In order to provide such conventional memory devices, a minimum of hundreds to thousands of processes may need to be performed, which reduces the manufacturing yield. In addition, dozens to thousands of patterns including gates, sources and drains may need to be formed, which makes it difficult to increase the integration density of memory devices.

In order to address the problems associated of DRAMs or flash memories and provide next-generation memory devices having the benefits of DRAMs and flash memories, various research has long been conducted.

The field of research of next-generation memory devices may be divided according to the material of which memory cells are made up. Many efforts have been made to store data using various materials. Exemplary materials include materials that become either crystalline or amorphous when a current is applied thereto, a ferroelectric material that polarizes itself when power is applied, a ferromagnetic material, and a conductive organic material.

However, it is necessary to optimize processing conditions for applying such materials to manufacture highly-integrated memory devices.

The use of conductive organic materials has not yet been widespread in manufacturing memory devices. A drawback to their use is that it is difficult to determine optimum processing conditions to manufacture memory devices using conductive organic materials. Further, low-molecular weight conductive organic materials, which have been widely used to manufacture conventional memory devices, are vulnerable to heat and are thus often likely to result in breakdown of the properties of memory devices, especially when the memory devices are operated at a temperature of above 200° C.

### SUMMARY OF THE INVENTION

Aspects of the present invention provide a conductive organic nonvolatile memory device which causes no data loss even when being powered off, consumes less power, contributes high integration density and which provides high operating speed, and a method of manufacturing the conductive organic nonvolatile memory device.

Aspects of the present invention also provide a nonvolatile memory device and a method of manufacturing the same, in which the bistable conduction property of an organic material may be maintained by establishing optimum processing conditions and the thermal stability of a nonvolatile memory device may also be maintained by using a conductive organic material having the properties of a polymer.

However, the aspects of the present invention are not restricted to those set forth herein. The above and other aspects of the present invention will become more apparent to one of ordinary skill in the art to which the present invention pertains by referencing a detailed description of the present invention given below.

According to an aspect of the present invention, there is provided a method of manufacturing a nonvolatile memory device, the method including: forming a lower conductive layer on a substrate; forming a first conductive organic layer on the substrate using spin coating, for example; forming a metal layer for forming nanocrystals on the first conductive organic layer, the metal layer partially overlapping the first conductive organic layer; forming a second conductive organic layer on the first conductive organic layer using spin coating, for example; transforming the metal layer into nanocrystals by curing; and forming an upper conductive layer on the second conductive organic layer, the upper conductive layer partially overlapping the nanocrystals.

The spin coating may include: forming mask patterns on the substrate; forming organic material on the substrate using spin coating; and removing the mask patterns and portions of the organic material on the mask patterns.

The forming the organic material may include using PVK or PS mixed in a solvent.

The forming the mask patterns may include: forming a photosensitive film on the substrate; performing a lithography operation on the photosensitive film; and performing an etching operation on the photosensitive film.

The forming the mask patterns may also include performing a baking operation on the photosensitive film at a temperature of about 100-150° C. for about 1-10 minutes, after the forming the photosensitive film.

The forming the organic material may include applying a liquid-phase conductive organic material on the substrate while rotating the substrate at about 1000-3000 rpm.

The forming the organic material may include applying a liquid-phase conductive organic material on the substrate and then rotating the substrate at about 1000-3000 rpm.

The curing may include curing at a temperature of about 200-400° C. for about 1-3 hours.

The forming the metal layer may include depositing at least one of Au, Pt, Ag, Ti, Ni, Cu and an alloy thereof using vacuum evaporation.

The depositing may include depositing the at least one of Au, Pt, Ag, Ti, Ni, Cu and an alloy thereof at a deposition rate of about 0.01-1.0 Å/s.

### BRIEF DESCRIPTION OF THE DRAWINGS

FIG. 1 illustrates a cross-sectional view of a nonvolatile memory device according to an embodiment of the present invention;

FIG. 2 shows a transmission electron microscope (TEM) image of the nonvolatile memory device shown in FIG. 1;

FIG. 3 illustrates an enlarged view of nanocrystals E of FIG. 2;

FIGS. 4 through 7 illustrate graphs of the current-voltage properties of a nonvolatile memory device having gold (Au) nanocrystals;

FIGS. 8 through 11 illustrate graphs of the current-voltage properties of a nonvolatile memory device having silver (Ag) nanocrystals;

FIGS. 12 through 18 illustrate diagrams of a method of manufacturing a nonvolatile memory device according to an embodiment of the present invention;

FIG. 19 illustrates a TEM image of a memory device obtained by the method of the embodiment of FIGS. 12 through 18;

FIGS. 20A through 20D illustrate energy dispersive spectroscopy (EDS) images of the distributions of various components of the memory device shown in FIG. 19;

FIG. 21 illustrates a graph of the physical properties of the memory device shown in FIG. 19;

FIGS. 22 through 27 illustrate TEM images of Au nanocrystals of various sizes obtained by the method of the embodiment of FIGS. 12 through 18; and

FIGS. 28A through 28C illustrate graphs of the current-voltage properties of memory devices having different conductive material concentrations.

### DETAILED DESCRIPTION OF THE EXEMPLARY EMBODIMENTS

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout. As used herein the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Furthermore, relative terms such as “below,” “beneath,” or “lower,” “above,” and “upper” may be used herein to describe one element's relationship to another element as illustrated in the accompanying drawings. It will be understood that relative terms are intended to encompass different orientations of the device in addition to the orientation depicted in the accompanying drawings. For example, if the device in the accompanying drawings is turned over, elements described as being on the “lower” side of other elements would then be oriented on “upper” sides of the other elements. Similarly, if the device in one of the figures is turned over, elements described as “below” or “beneath” other elements would then be oriented “above” the other elements. Therefore, the exemplary terms “below” and “beneath” can, therefore, encompass both an orientation of above and below.

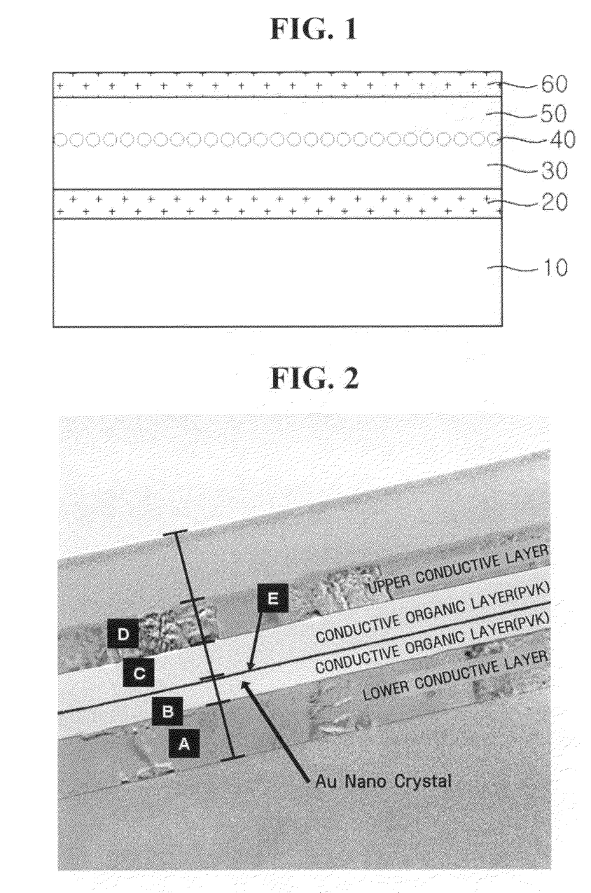

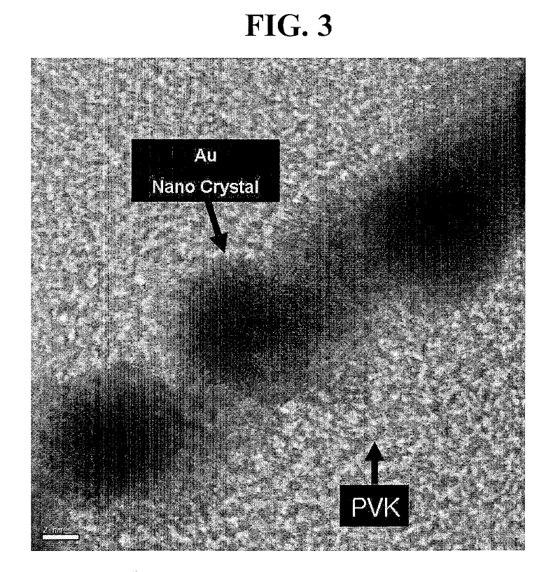

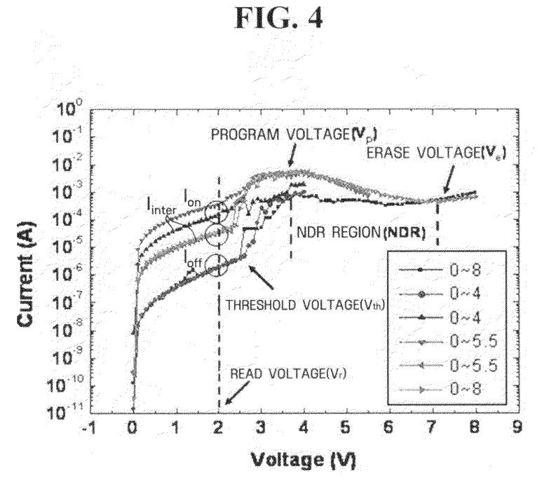

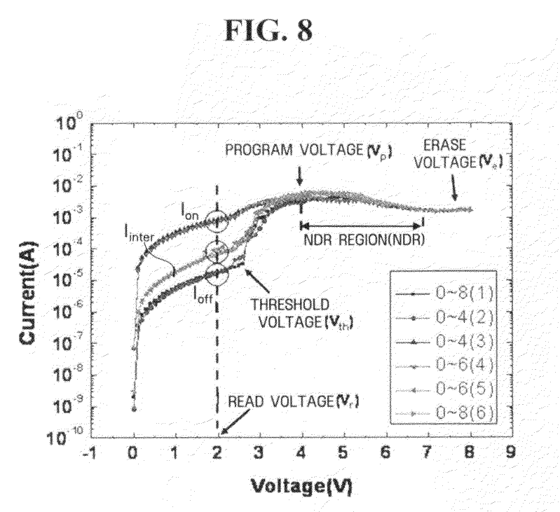

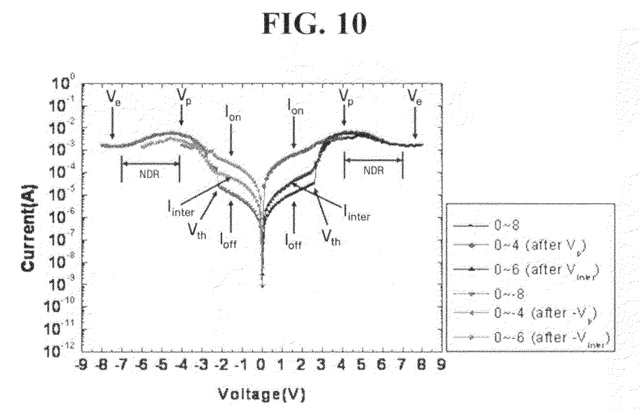

FIG. 1 illustrates a cross-sectional view of a nonvolatile memory device according to an embodiment of the present invention; FIG. 2 shows a transmission electron microscope (TEM) image of the nonvolatile memory device illustrated in FIG. 1; FIG. 3 illustrates an enlarged view of nanocrystals E of FIG. 2; FIGS. 4 through 7 illustrate graphs of the current-voltage properties of nonvolatile memory devices having gold (Au) nanocrystals; and, FIGS. 8 through 11 illustrate graphs of the current-voltage properties of nonvolatile memory devices having silver (Ag) nanocrystals. Referring to FIG. 2, reference character A indicates a lower conductive layer, reference characters B and C indicate conductive organic layers, D indicates an upper conductive layer, and E represents an Au nanocrystal.

Referring to FIGS. 1 through 11, the nonvolatile memory device may include lower and upper conductive layers 20 and 60, first and second conductive organic layers 30 and 50, which may be interposed between the lower and upper conductive layers 20 and 60 and have a bistable conduction property, and nanocrystals 40 which may be interposed between the first and second conductive organic layers 30 and 50. The nanocrystals 40, which may be formed between the first and second conductive organic layers 30 and 50, may include nanocrystal dots (e.g., Au nanocrystal dots), as indicated by FIGS. 2 and 3.

The first and second conductive organic layers 30 and 50 may be formed of a conductive polymer material whose properties include conductive properties that do not change even at high temperatures (e.g., at a temperature of 300° C. or higher). The first and second conductive organic layers 30 and 50 may form a multilayer structure, and the nanocrystals 40 may be formed between the first and second conductive organic layers 30 and 50. That is, for example, referring to FIG. 1, the lower conductive layer 20 is disposed on a substrate 10, the first conductive organic layer 30 is disposed on the lower conductive layer 20, the nanocrystals 40 is disposed on the first conductive organic layer 30, and the second conductive organic layer 50 is disposed on the nanocrystals 40, and the upper conductive layer 60 is disposed on the second conductive organic layer 50.

The substrate 10 may be an insulating substrate, a semiconductor substrate or a conductive substrate. More specifically, the substrate 10 may be a plastic substrate, a glass substrate, an Al₂O₃ substrate, a SiC substrate, a ZnO substrate, a Si substrate, a GaAs substrate, a GaP substrate, a LiAl₂O₃ substrate, a BN substrate, an AlN substrate, a silicon-on-insulator (SOI) substrate or a GaN substrate. Alternatively, the substrate 10 may be a conductive substrate. In this case, the substrate 10 may be isolated from the lower conductive layer 20 by a dielectric material. Alternatively, the substrate 10 may be a silicon (Si) substrate on which an oxide layer (SiO₂) is deposited.

The lower and upper conductive layers 20 and 60 may be formed of nearly all materials having electric conductivity. More specifically, the lower and upper conductive layers 20 and 60 may be formed of Al, Au, Pt, Ag, Ti, Ni, Cu or an alloy thereof.

The first and second conductive organic layers 30 and 50 may be formed of poly-N-vinylcarbazole (PVK) or polystyrene (PS). PVK, sometimes represented as PNVK or PVCa or PVCz, is represented by Chemical Formula (1):

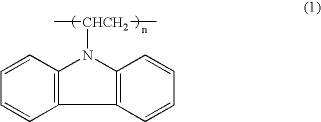

wherein n is an integer of one or greater than one.

PS is represented by Chemical Formula (2):

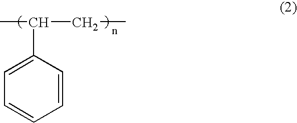

wherein n is an integer of one or greater than one. Alternatively, the conductive organic layer 30 may be formed of (AlDCN), naphthyl phenylciamine (α-NPD) or tris-(8-hydroxyquinaline) aluminum (Alq₃).

Conductive organic materials such as PVK and PS may have a bistable conduction property, i.e., have two different conductivities at the same voltage. In addition, conductive organic materials such as PVK and PS may be used even at a temperature of 300° C. or higher. Thus, it may be possible to increase the processing temperature of a memory device and prevent the conductive organic properties of a memory device from breaking down at temperatures of 300° C. and higher, such as during a passivation operation.

The nanocrystals 40 may be formed of Au, Pt, Ag, Cu, Ti, Ni or an alloy thereof. That is, it may be possible to uniformly form and distribute nanocrystals having a uniform size in a conductive organic layer by using a metal that minimally oxidizes. The nanocrystals 40 may be formed of Au and/or Ag. Further, nanocrystals 40 may be spaced apart from each other.

The operation of a nanocrystal-based nonvolatile memory device, for example, using Au nanocrystals, according to an embodiment of the present invention will hereinafter be described in detail with reference to FIGS. 4 through 8.

The Au nanocrystal-based nonvolatile memory device, like the nonvolatile memory device of FIGS. 1 through 3, may include lower and upper conductive layers 20 and 60 and a stack of a conductive organic layer 30, nanocrystals 40 (e.g., an Au nanocrystals) and a conductive organic layer 50, which are interposed between the lower and upper conductive layers 20 and 60. When a voltage is applied to the lower and upper conductive layers 20 and 60, the Au nanocrystal-based nonvolatile memory device may have various currents Iₒₙ, I_{off}, and Iᵢₙₜₑᵣ in response to a certain range of voltages (Vᵣ=2 V where Vᵣ indicates a read voltage), as illustrated in FIG. 4.

The currents Iₒₙ, Iᵢₙₜₑᵣ and I_{off} respectively correspond to a high-current (low-resistance) state that occurs at the read voltage Vᵣ after the application of a program voltage Vₚ, an intermediate current (intermediate-resistance) state that occurs at the read voltage Vᵣ after the application of a negative differential resistance (NDR) voltage V_{NDR}, and a low-current (high-resistance) state that occurs at the read voltage Vᵣ after the application of an erase voltage Vₑ.

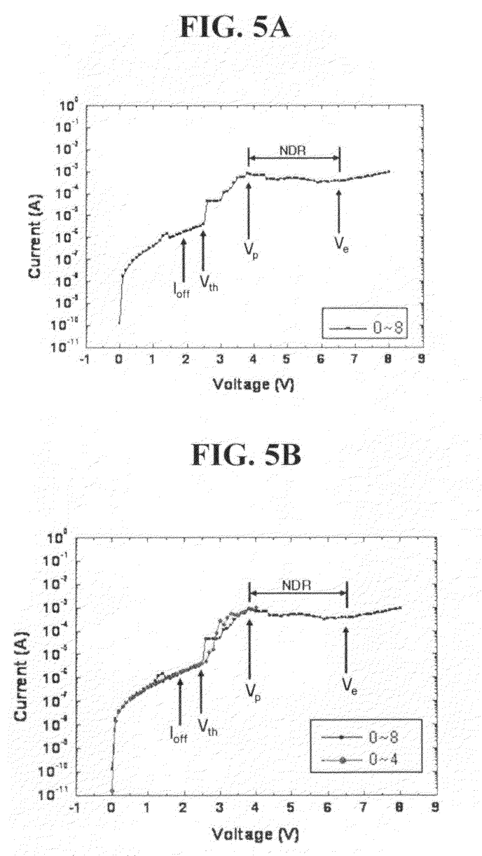

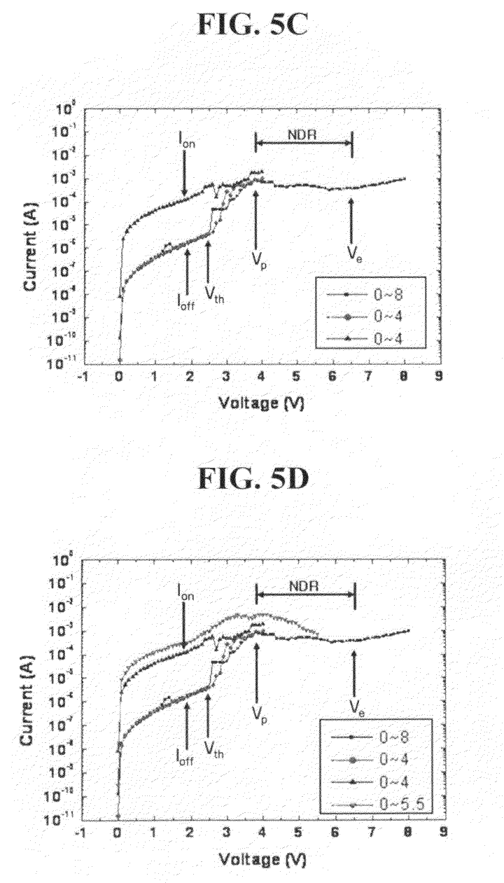

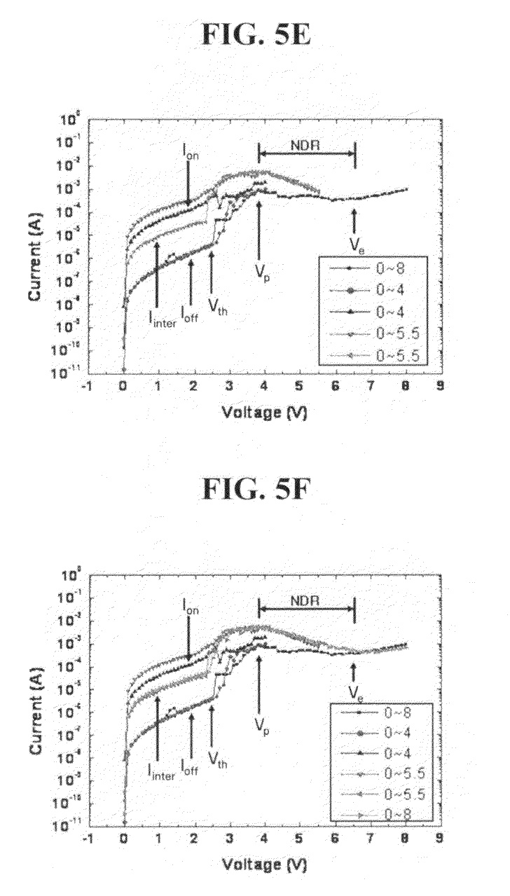

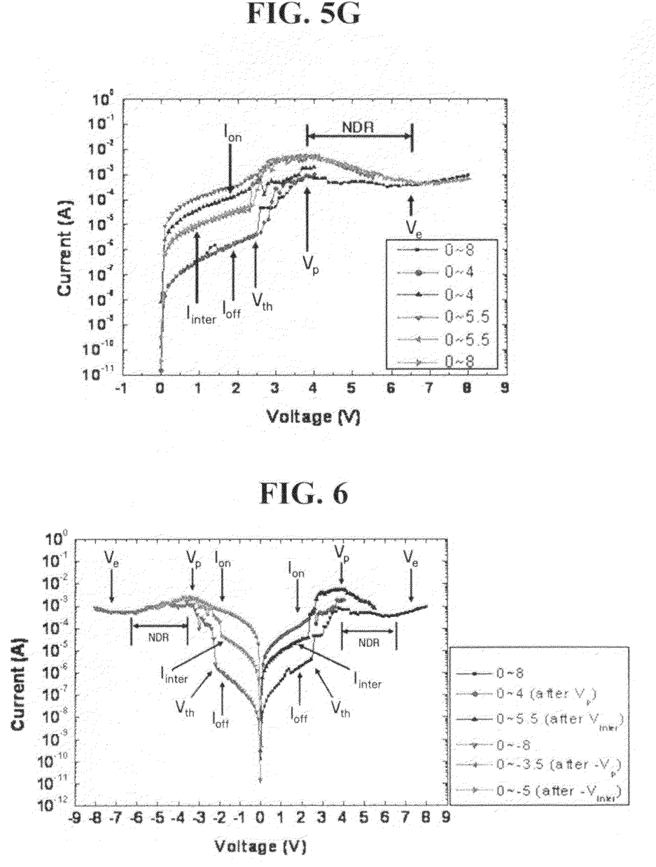

For example, if the lower conductive layer 20 is connected to a ground, the upper conductive layer 60 is connected to a predetermined voltage source, and the voltage of the voltage source is continually increased toward a positive direction, the current of the Au nanocrystal-based nonvolatile memory device slowly increases until a threshold voltage Vₜₕ or a voltage higher than the threshold voltage Vₜₕ is applied. Thereafter, if the threshold voltage Vₜₕ is applied, the current of the Au nanocrystal-based nonvolatile memory device rapidly increases until the voltage of the Au nanocrystal-based nonvolatile memory device reaches the program voltage Vₚ. Thereafter, if a voltage higher than the threshold voltage Vₜₕ is applied, an NDR state may occur, and the voltage of the Au nanocrystal-based nonvolatile memory device may reach the erase voltage Vₑ. Thereafter, the current of the Au nanocrystal-based nonvolatile memory device increases again according to a voltage applied to the Au nanocrystal-based nonvolatile memory device, as illustrated in FIG. 5A.

If the voltage of the upper conductive layer 60 is continually increased from 0 V to the program voltage Vₚ toward the positive direction, as illustrated in FIG. 5B, and then continually increased again from 0 V to the program voltage Vₚ toward the positive direction, charge may accumulate on the surface of the Au nanocrystals 40, and thus, the current of the Au nanocrystal-based nonvolatile memory device may increase and may thus be placed in the high-current state (Iₒₙ), as illustrated in FIG. 5C. Thereafter, if the voltage of the upper conductive layer 60 is continually increased from 0 V to the NDR voltage V_{NDR} toward the positive direction, the Au nanocrystal-based nonvolatile memory device may reach an NDR region, as illustrated in FIG. 5D. Thereafter, if the voltage of the upper conductive layer 60 is continually increased again from 0 V to the voltage V_{NDR} toward the positive direction, a new current path, i.e., the path of the current Iᵢₙₜₑᵣ, may appear, as illustrated in FIG. 5E. Thereafter, if the voltage of the upper conductive layer 60 is continually increased from 0 V to the erase voltage Vₑ toward the positive direction, the current Iᵢₙₜₑᵣ may flow in the Au nanocrystal-based nonvolatile memory device, and the charge accumulated on the Au nanocrystals 40 may be erased while the voltage of the Au nanocrystal-based nonvolatile memory device is increased up to the erase voltage V_{c} through the program voltage Vₚ and the NDR voltage V_{NDR}, as illustrated in FIG. 5F. Thereafter, if the program voltage Vₚ, the NDR voltage V_{NDR}, the erase voltage Vₑ, and a voltage of 0V are applied to the Au nanocrystal-based nonvolatile memory device, charge may accumulate again on the Au nanocrystals 40, and thus, the Au nanocrystal-based nonvolatile memory device may be placed in the high-current state (Iₒₙ), as illustrated in FIG. 5G.

If the Au nanocrystals 40 are yet to be charged with carriers due to the difference between the energy level of the Au nanocrystals 40 and the energy level of the first and second conductive organic layers 30 and 50, the Au nanocrystal-based nonvolatile memory device may be placed in the low-current state (I_{off}), i.e., the current of the Au nanocrystal-based nonvolatile memory device may slightly increase according to a voltage applied thereto, until the threshold voltage Vₜₕ is applied to the Au nanocrystal-based nonvolatile memory device. However, if the threshold voltage Vₜₕ or a voltage higher than the threshold voltage Vₜₕ is applied to the first and second conductive organic layers 30 and 50, the Au nanocrystals 40 may be charged with carriers, and thus the current of the Au nanocrystal-based nonvolatile memory device may rapidly increase. The current of the Au nanocrystal-based nonvolatile memory device may be dozens to thousands of times higher when the Au nanocrystals 40 is charged with carriers than when the Au nanocrystals 40 is yet to be charged with carriers. If the NDR voltage V_{NDR} is applied to the first and second conductive organic layers 30 and 50, the Au nanocrystals 40 may be partially discharged or may be partially charged with carriers. Thus, the current of the Au nanocrystal-based nonvolatile memory device may become lower than the current Iₒₙ and higher than the current I_{off}. If a voltage higher than the NDR voltage V_{NDR}, i.e., the erase voltage Vₑ, is applied to the first and second conductive organic layers 30 and 50, the Au nanocrystals may be completely discharged.

If the voltage of the predetermined voltage source is continually increased toward a negative direction, the current of the Au nanocrystal-based nonvolatile memory device may slowly increase until the voltage of the Au nanocrystal-based nonvolatile memory device reaches the threshold voltage Vₜₕ. Once the voltage of the Au nanocrystal-based nonvolatile memory device reaches the threshold voltage Vₜₕ, the current of the Au nanocrystal-based nonvolatile memory device may rapidly increase. Thereafter, if the voltage of the Au nanocrystal-based nonvolatile memory device reaches the program voltage Vₚ and then a voltage higher than the threshold voltage Vₜₕ is applied to the Au nanocrystal-based nonvolatile memory device, the Au nanocrystal-based nonvolatile memory device may be placed in the NDR state, i.e., the current of the Au nanocrystal-based nonvolatile memory device may decrease according to the voltage applied thereto. Thereafter, if a voltage higher than the erase voltage Vₑ is applied to the Au nanocrystal-based nonvolatile memory device, the current of the Au nanocrystal-based nonvolatile memory device may slowly increase according to the voltage applied thereto, as illustrated in FIG. 6. In this case, the same mechanism as that described above with reference to FIGS. 5A through 5G may be applied to the Au nanocrystal-based nonvolatile memory device because the Au nanocrystal-based nonvolatile memory device has a symmetrical structure.

Referring to FIG. 4, if a voltage of 2 V is applied to the Au nanocrystal-based nonvolatile memory device when the Au nanocrystals 40 are yet to be charged with carriers, a current of about 2×10⁻⁶ may flow in the Au nanocrystal-based nonvolatile memory device. If the voltage of 2 V is applied to the Au nanocrystal-based nonvolatile memory device when the Au nanocrystals 40 are fully charged with carriers, a current of about 1×10⁻⁴ may flow in the Au nanocrystal-based nonvolatile memory device. If the voltage of 2 V is applied to the Au nanocrystal-based nonvolatile memory device when the Au nanocrystals 40 are partially charged with carriers, a current of about 2×10⁻⁵ may flow in the Au nanocrystal-based nonvolatile memory device. This bistable conduction property enables the Au nanocrystal-based nonvolatile memory device to perform the functions of a typical nonvolatile memory device such as write, read and erase functions.

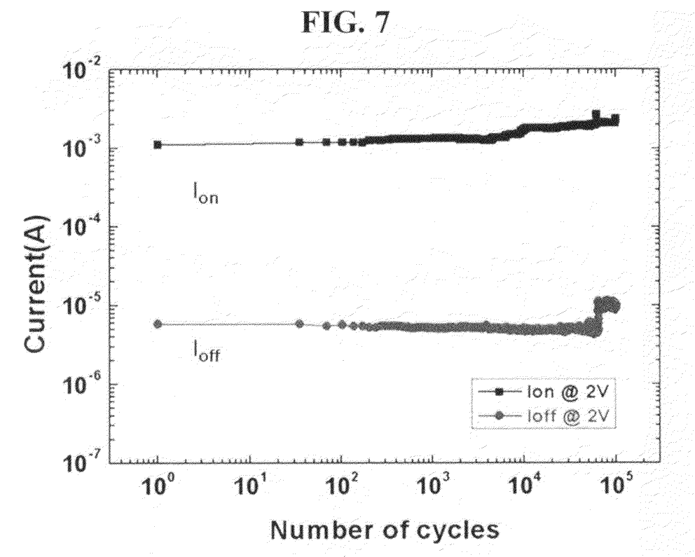

If a write voltage, i.e., the program voltage Vₚ, is applied to the Au nanocrystal-based nonvolatile memory device, carriers may accumulate in the Au nanocrystals 40, and thus, a logic high value (Iₒₙ) of 1 may be written to the Au nanocrystal-based nonvolatile memory device. The program voltage Vₚ may be within a range of 3 to 4 V. Once data is written to the Au nanocrystal-based nonvolatile memory device, the data is never erased even when the Au nanocrystal-based nonvolatile memory device is powered off, as illustrated in FIG. 7.

Thereafter, if the erase voltage Vₑ is applied to the Au nanocrystal-based nonvolatile memory device, the carriers accumulated in the Au nanocrystals 40 may be discharged, and thus the data written to the Au nanocrystal-based nonvolatile memory device may be erased and thus replaced with a logic low value (I_{off}) of 0. The erase voltage Vₑ may be 7 V or higher. Once the data written to the Au nanocrystal-based nonvolatile memory device is erased, the Au nanocrystal-based nonvolatile memory device maintains its state even after being powered off, as illustrated in FIG. 7.

If an intermediate write voltage, i.e., the NDR voltage V_{NDR}, is applied to the Au nano crystal-based nonvolatile memory device, the Au nanocrystals 40 may be partially charged with carriers, and thus, a data value between the logic high value (Iₒₙ) and the logic low value (I_{off}) may be written to the Au nanocrystal-based nonvolatile memory device. The NDR voltage V_{NDR} may be within a range of 4 to 7 V. Various currents may be provided between the currents Iₒₙ and I_{off} according to the magnitude of the NDR voltage V_{NDR}. Thus, it is possible to realize multi-level cells (MLCs). In particular, as the higher the ratio of the currents Iₒₙ and I_{off} increases, the number of MLCs that can be provided increases.

If a read voltage Vᵣ is applied to the Au nano crystal-based nonvolatile memory device, the current of the Au nano crystals 40 may considerably vary according to whether and how much the Au nanocrystals 40 are charged with carriers. Then, data written to the Au nanocrystal-based nonvolatile memory device may be read by analyzing the variation in the current of the Au nanocrystals 40. More specifically, if the variation in the current of the Au nanocrystals 40 are less than a reference value, it may be determined that no data has been written to the Au nanocrystals 40, and a data value of 0 may be read from the Au nanocrystal-based nonvolatile memory device. If the variation in the current of the Au nanocrystals 40 are greater than a reference value, it may be determined that data has been written to the Au nanocrystals 40, and a data value of 1 may be read from the Au nanocrystal-based nonvolatile memory device. If the variation in the current of the Au nanocrystals 40 are greater than the reference value and is less than when the data value of 1 is read from the Au nanocrystal-based nonvolatile memory device, it is determined that data has been partially written to the Au nanocrystals 40, and a data value corresponding to an intermediate state may be read from the Au nanocrystal-based nonvolatile memory device. The read voltage Vᵣ may be within a range of about 0.1 to 2.5 V. In this manner, it is possible to perform the functions of an MLC memory device.

The above-mentioned logic values may be altered according to the direction of a current flow.

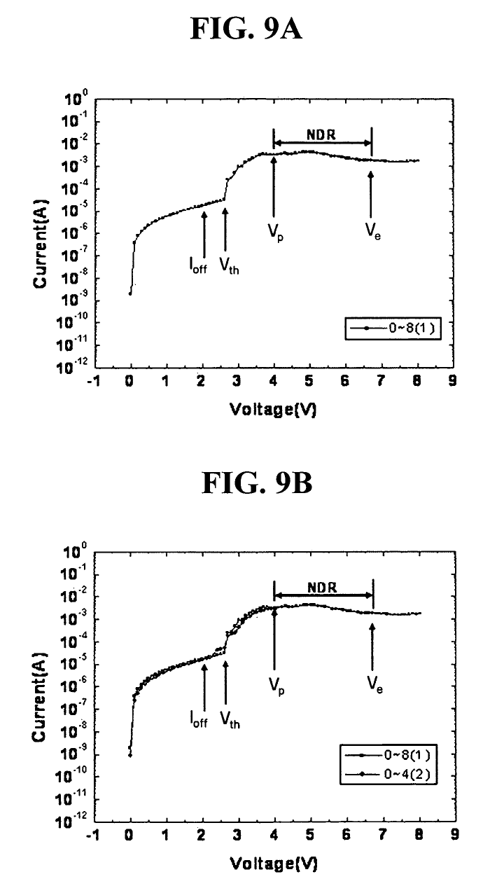

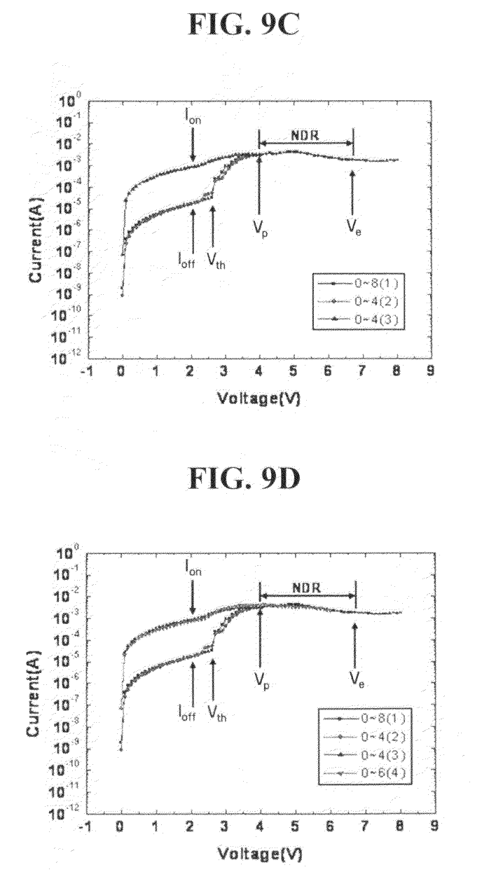

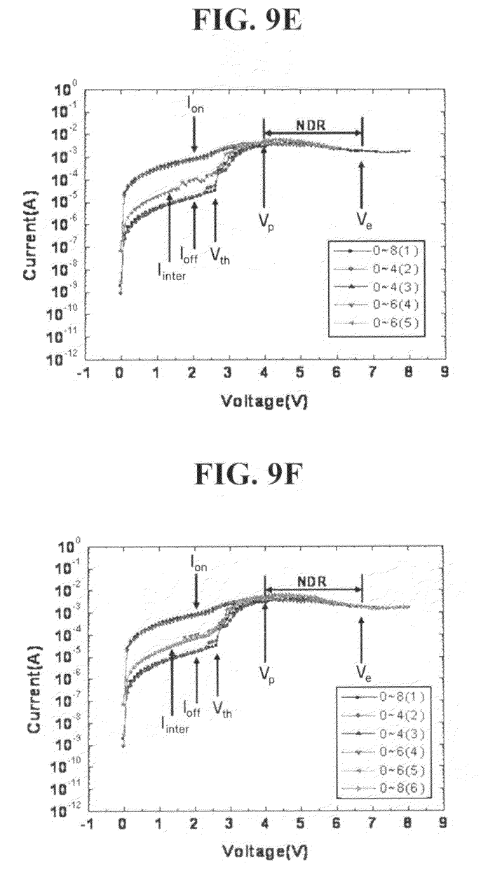

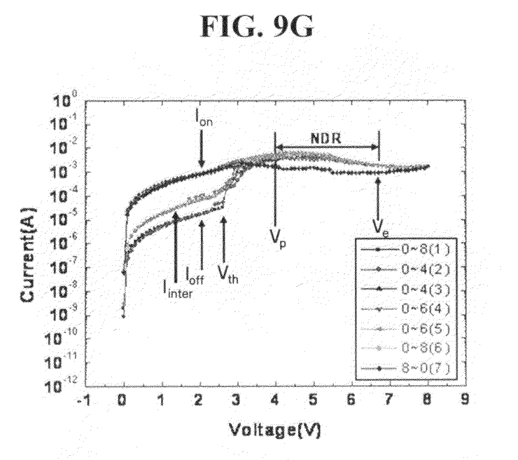

The operation of a nonvolatile memory device using Ag nanocrystals, according to an embodiment of the present invention will hereinafter be described in detail with reference to FIGS. 9A through 11.

The Ag nanocrystal-based nonvolatile memory device, like the nonvolatile memory device of FIGS. 1 through 3, may include lower and upper conductive layers 20 and 60 and a stack of a conductive organic layer 30, an Ag nanocrystals 40 and a conductive organic layer 50, which are interposed between the lower and upper conductive layers 20 and 60. When a voltage is applied to the lower and upper conductive layers 20 and 60, the Ag nanocrystal-based nonvolatile memory device has various currents Iₒₙ, I_{off}, and Iᵢₙₜₑᵣ in response to a certain range of voltages (Vᵣ=2 V where Vᵣ indicates a read voltage), as illustrated in FIG. 8.

The currents Iₒₙ, Iᵢₙₜₑᵣ and I_{off} respectively correspond to a high-current (low-resistance) state that occurs at the read voltage Vᵣ after the application of a program voltage Vₚ, an intermediate current (intermediate-resistance) state that occurs at the read voltage Vᵣ after the application of an NDR voltage V_{NDR}, and a low-current (high-resistance) state that occurs at the read voltage Vᵣ after the application of an erase voltage Vₑ.

For example, if the lower conductive layer 20 is connected to a ground, the upper conductive layer 60 is connected to a predetermined voltage source, and the voltage of the voltage source is continually increased toward a positive direction, the current of the Ag nanocrystal-based nonvolatile memory device slowly increases until a threshold voltage Vₜₕ or a voltage higher than the threshold voltage Vₜₕ is applied. Thereafter, if the threshold voltage Vₜₕ is applied, the current of the Ag nanocrystal-based nonvolatile memory device rapidly increases until the voltage of the Ag nanocrystal-based nonvolatile memory device reaches the program voltage Vₚ. Thereafter, if a voltage higher than the threshold voltage Vₜₕ is applied, the NDR state may occur, and the voltage of the Ag nanocrystal-based nonvolatile memory device may reach the erase voltage Vₑ. Thereafter, the current of the Ag nanocrystal-based nonvolatile memory device increases again according to a voltage applied to the Ag nanocrystal-based nonvolatile memory device, as illustrated in FIG. 9A.

If the voltage of the upper conductive layer 60 is continually increased from 0 V to the program voltage Vₚ toward the positive direction, as illustrated in FIG. 9B, and then continually increased again from 0 V to the program voltage Vₚ toward the positive direction, charge may accumulate on the surface of the Ag nanocrystals 40, and thus, the current of the Ag nanocrystal-based nonvolatile memory device may increase and may thus be placed in the high-current state (Iₒₙ), as illustrated in FIG. 9C. Thereafter, if the voltage of the upper conductive layer 60 is continually increased from 0 V to the NDR voltage V_{NDR} toward the positive direction, the Ag nanocrystal-based nonvolatile memory device may reach an NDR region, as illustrated in FIG. 9D. Thereafter, if the voltage of the upper conductive layer 60 is continually increased again from 0 V to the voltage V_{NDR} toward the positive direction, a new current path, i.e., the path of the current Iᵢₙₜₑᵣ, may appear, as illustrated in FIG. 9E. Thereafter, if the voltage of the upper conductive layer 60 is continually increased from 0 V to the erase voltage Vₑ toward the positive direction, the current Iᵢₙₜₑᵣ may flow in the Ag nanocrystal-based nonvolatile memory device, and the charge accumulated on the Ag nanocrystals 40 may be erased while the voltage of the Ag nanocrystal-based nonvolatile memory device is increased up to the erase voltage Vₑ through the program voltage Vₚ and the NDR voltage V_{NDR}, as illustrated in FIG. 9F. Thereafter, if the program voltage Vₚ, the NDR voltage V_{NDR}, the erase voltage Vₑ, and a voltage of 0V are applied to the Ag nanocrystal-based nonvolatile memory device, charge may accumulate again on the Ag nanocrystals 40, and thus, the Ag nanocrystal-based nonvolatile memory device may be placed in the high-current state (Iₒₙ), as illustrated in FIG. 9G.

If the Ag nanocrystals 40 are yet to be charged with carriers due to the difference between the energy level of the Ag nanocrystals 40 and the energy level of the first and second conductive organic layers 30 and 50, the Ag nanocrystal-based nonvolatile memory device may be placed in the low-current state (I_{off}), i.e., the current of the Ag nanocrystal-based nonvolatile memory device may slightly increase according to a voltage applied thereto, until the threshold voltage Vₜₕ is applied to the Ag nanocrystal-based nonvolatile memory device. However, if the threshold voltage Vₜₕ or a voltage higher than the threshold voltage Vₜₕ is applied to the first and second conductive organic layers 30 and 50, the Ag nanocrystals 40 may be charged with carriers, and thus the current of the Ag nanocrystal-based nonvolatile memory device may rapidly increase. The current of the Ag nanocrystal-based nonvolatile memory device is dozens to thousands of times higher when the Ag nanocrystals 40 are charged with carriers than when the Ag nanocrystals 40 are yet to be charged with carriers. If the NDR voltage V_{NDR} is applied to the first and second conductive organic layers 30 and 50, the Ag nanocrystals 40 may be partially discharged or may be partially charged with carriers. Thus, the current of the Ag nanocrystal-based nonvolatile memory device may become lower than the current Iₒₙ and higher than the current I_{off}. If a voltage higher than the NDR voltage V_{NDR}, i.e., the erase voltage Vₑ, is applied to the first and second conductive organic layers 30 and 50, the Ag nanocrystals may be completely discharged.

If the voltage of the predetermined voltage source is continually increased toward a negative direction, the current of the Ag nanocrystal-based nonvolatile memory device may slowly increase until the voltage of the Ag nanocrystal-based nonvolatile memory device reaches the threshold voltage Vₜₕ. Once the voltage of the Ag nanocrystal-based nonvolatile memory device reaches the threshold voltage Vₜₕ, the current of the Ag nanocrystal-based nonvolatile memory device may rapidly increase. Thereafter, if the voltage of the Ag nanocrystal-based nonvolatile memory device reaches the program voltage Vₚ and then a voltage higher than the threshold voltage Vₜₕ is applied to the Ag nanocrystal-based nonvolatile memory device, the Ag nanocrystal-based nonvolatile memory device may be placed in the NDR state, i.e., the current of the Ag nanocrystal-based nonvolatile memory device may decrease according to the voltage applied thereto. Thereafter, if a voltage higher than the erase voltage Vₑ is applied to the Ag nanocrystal-based nonvolatile memory device, the current of the Ag nanocrystal-based nonvolatile memory device may slowly increase according to the voltage applied thereto, as illustrated in FIG. 6. In this case, the same mechanism as that described above with reference to FIGS. 5A through 5G may be applied to the Ag nanocrystal-based nonvolatile memory device because the Ag nanocrystal-based nonvolatile memory device has a symmetrical structure.

Referring to FIG. 8, if a voltage of 2 V is applied to the Ag nanocrystal-based nonvolatile memory device when the Ag nanocrystals 40 are yet to be charged with carriers, a current of about 2×10⁻⁶ may flow in the Ag nanocrystal-based nonvolatile memory device. If the voltage of 2 V is applied to the Ag nanocrystal-based nonvolatile memory device when the Ag nanocrystals 40 are fully charged with carriers, a current of about 1×10⁻⁴ may flow in the Ag nanocrystal-based nonvolatile memory device. If the voltage of 2 V is applied to the Ag nanocrystal-based nonvolatile memory device when the Ag nanocrystals 40 are partially charged with carriers, a current of about 2×10⁻⁵ may flow in the Ag nanocrystal-based nonvolatile memory device. This bistable conduction property enables the Ag nanocrystal-based nonvolatile memory device to perform the functions of a typical nonvolatile memory device such as write, read and erase functions.

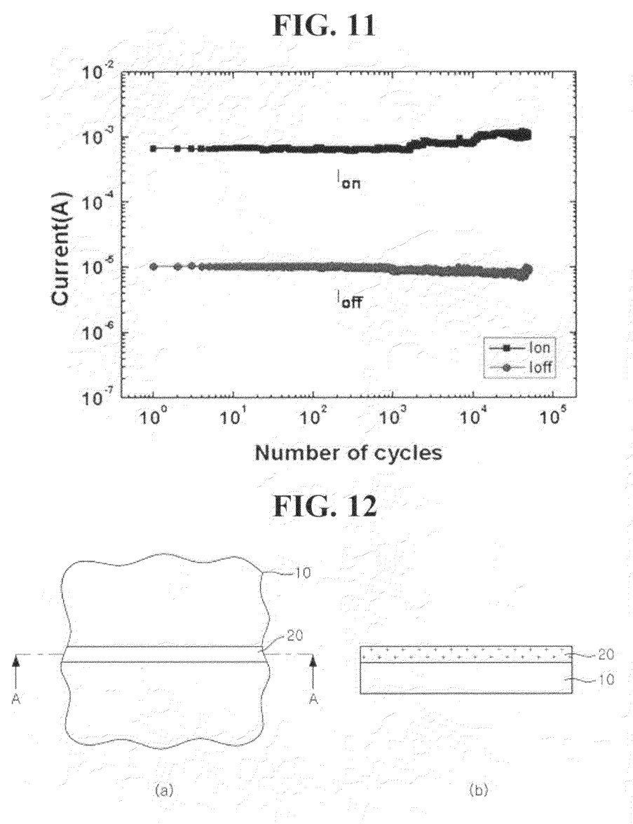

If a write voltage, i.e., the program voltage Vₚ, is applied to the Ag nanocrystal-based nonvolatile memory device, carriers may accumulate in the Ag nanocrystals 40, and thus, a logic high value (Iₒₙ) of 1 may be written to the Ag nanocrystal-based nonvolatile memory device. The program voltage Vₚ may be within the range of 3 to 4 V. Once data is written to the Ag nanocrystal-based nonvolatile memory device, the data is never erased even when the Ag nanocrystal-based nonvolatile memory device is powered off, as illustrated in FIG. 11.

Thereafter, if the erase voltage Vₑ is applied to the Ag nanocrystal-based nonvolatile memory device, the carriers accumulated in the Ag nanocrystals 40 may be discharged, and thus the data written to the Ag nanocrystal-based nonvolatile memory device may be erased and thus replaced with a logic low value (I_{off}) of 0. The erase voltage Vₑ may be 7 V or higher. Once the data written to the Ag nanocrystal-based nonvolatile memory device is erased, the Ag nanocrystal-based nonvolatile memory device maintains its state even after being powered off, as illustrated in FIG. 11.

If an intermediate write voltage, i.e., the NDR voltage V_{NDR}, is applied to the Ag nanocrystal-based nonvolatile memory device, the Ag nanocrystals 40 may be partially charged with carriers, and thus, a data value between the logic high value (Iₒₙ) and the logic low value (I_{off}) may be written to the Ag nanocrystal-based nonvolatile memory device. The NDR voltage V_{NDR} may be within a range of about 4 to 7 V. Various currents may be provided between the currents Iₒₙ and I_{off} according to the magnitude of the NDR voltage V_{NDR}. Thus, it is possible to realize multi-level cells (MLCs). In particular, as the higher the ratio of the currents Iₒₙ and I_{off} increases, the number of MLCs that can be provided increases.

If a read voltage Vᵣ is applied to the Ag nanocrystal-based nonvolatile memory device, the current of the Ag nanocrystals 40 may considerably vary according to whether and how much the Ag nanocrystals 40 are charged with carriers. Then, data written to the Ag nanocrystal-based nonvolatile memory device may be read by analyzing the variation in the current of the Ag nanocrystals 40. More specifically, if the variation in the current of the Ag nanocrystals 40 are less than a reference value, it may be determined that no data has been written to the Ag nanocrystals 40, and a data value of 0 may be read from the Ag nanocrystal-based nonvolatile memory device. If the variation in the current of the Ag nanocrystals 40 is greater than a reference value, it may be determined that data has been written to the Ag nanocrystals 40, and a data value of 1 may be read from the Ag nanocrystal-based nonvolatile memory device. If the variation in the current of the Ag nanocrystals 40 are greater than the reference value and is less than when the data value of 1 is read from the Ag nanocrystal-based nonvolatile memory device, it is determined that data has been partially written to the Ag nanocrystals 40, and a data value corresponding to an intermediate state may be read from the Ag nanocrystal-based nonvolatile memory device. The read voltage Vᵣ may be within a range of about 0.1 to 2.5 V. In this manner, it is possible to perform the functions of an MLC memory device.

A set of processing conditions for the manufacture of a nonvolatile memory device having the above-mentioned bistable conduction property and a method of manufacturing the nonvolatile memory device will hereinafter be described in detail.

FIGS. 12 through 18 illustrate diagrams for explaining a method of manufacturing a nonvolatile memory device according to an embodiment of the present invention. More specifically, FIGS. 12(a), 13(a), 14(a), 15(a), 16(a), 17(a), and 18(a) illustrate plan views for explaining a method of manufacturing a nonvolatile memory device according to an embodiment of the present invention, and FIGS. 12(b), 13(b), 14(b), 15(b), 16(b), 17(b), and 18(b) illustrate cross-sectional views taken along line A-A of FIGS. 12(a), 13(a), 14(a), 15(a), 16(a), 17(a), and 18(a).

Referring to FIGS. 12(a) and 12(b), a lower conductive layer 20 is formed on a substrate 10. More specifically, the lower conductive layer 20 may be formed as a straight line by using an evaporation method. The substrate 10 may be a silicon substrate or a glass substrate, and a dielectric layer may be additionally deposited on the substrate 10. The dielectric layer may be an oxide layer or a nitride layer.

Thereafter, the substrate 10 is loaded in a chamber (not shown) for the deposition of a metal, and a portion of the substrate 10 on which the lower conductive layer 20 is to be formed is exposed by using a first shadow mask (not shown). Thereafter, the lower conductive layer 20 is formed on the exposed portion of the substrate 10 by evaporating a metal at a temperature of about 1000 to 1500° C. and at a deposition rate of about 1 to 10 Å/s while maintaining the pressure in the chamber at a range of about 5×10⁻⁷ to 5×10⁻⁵ Pa. The lower conductive layer 20 may be formed of Al to a thickness of about 50-100 nm. The lower conductive layer 20 may be formed as a horizontal straight line. A rinsing operation may be performed before or after the deposition of the lower conductive layer 20 on the substrate 10.

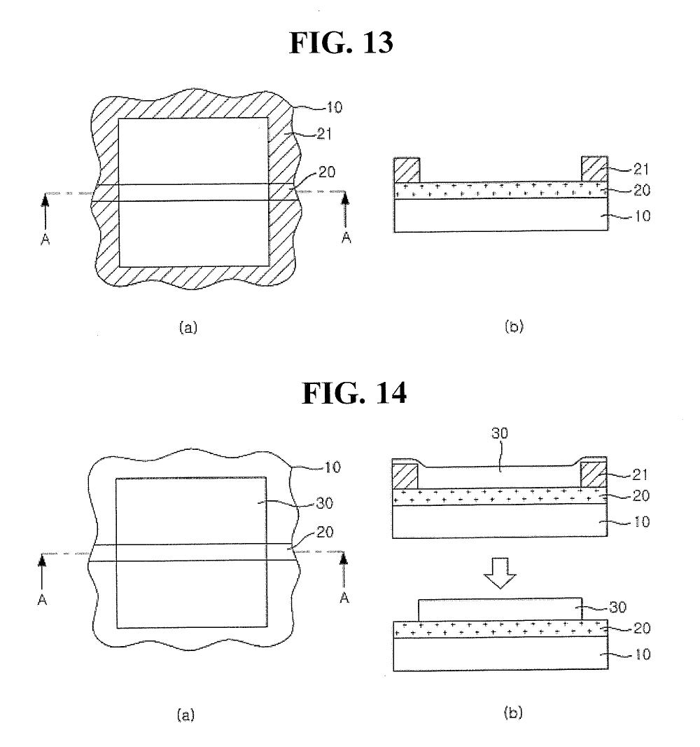

Referring to FIGS. 13 and 14, a first conductive organic layer 30 is formed on the substrate 10 on which the lower conductive layer 20 is formed. More specifically, mask patterns 21 that expose a portion of the substrate 10 on which the first conductive organic layer 30 is to be formed is formed on the substrate 10, and the substrate 10 is coated with an organic material by using spin coating. Thereafter, the mask patterns 21 and portions of the organic material on the mask patterns 21 are removed, thereby forming the first conductive organic layer 30, which overlaps part of the lower conductive layer 20.

The mask patterns 21 may be formed of a material having high etching selectivity to the organic material. For example, the mask patterns 21 may include an oxide layer or a nitride layer. Alternatively, the mask patterns 21 may include a photosensitive film, and this will hereinafter be described in further detail.

First photosensitive film patterns 21 that expose the portion of the substrate 10 on which the first conductive organic layer 30 is to be formed are formed by patterning a photosensitive film. More specifically, a photosensitive film is formed on the substrate 10. The photosensitive may be formed on the substrate 10 by rotating the substrate 10 at about 500-4000 rpm using spin coating. For example, the photosensitive film may be uniformly formed on the substrate 10 by dropping a photoresist solution onto the substrate 10 while rotating the substrate 10 at about 1000 rpm and then increasing the rotation speed of the substrate 10 to about 3000 rpm. Alternatively, the photosensitive film may be uniformly formed by dropping a photoresist solution onto the substrate 10 and then rotating the substrate 10.

Thereafter, a baking operation is performed on the photosensitive film at a temperature of about 100-150° C. for about 1 to 10 minutes. Thereafter, a lithography operation for forming a mask is performed. During the lithography operation, various types of beams may be used. More specifically, ultraviolet (UV) rays may be used during the lithography operation. The photosensitive film may be patterned through an etching operation, thereby forming the first photosensitive film patterns 21, which expose the portion of the substrate 10 on which the first conductive organic layer 30 is to be formed. The etching operation may be a wet etching operation that involves the use of a chemical solution such as an acetone solution. The etching operation may be performed for about 45 seconds to 1 minute.

Due to the properties of the photosensitive film, either light-exposed portions or non-light-exposed portions of the photosensitive film may be etched away during the etching operation. During the lithography operation, light may be irradiated on a portion of the photosensitive film on which the first conductive organic layer 30 is to be formed. Then, the light-exposed portion of the photosensitive portion may be removed, thereby forming the first photosensitive patterns 21. A rinsing operation may be performed after the formation of the first photosensitive patterns 21.

Thereafter, an organic material may be applied on the entire surface of the substrate 10 by using spin coating or other techniques, the selection of which will be within the skill of one in the art. Thereafter, the first photosensitive patterns 21 and portions of the organic material on the first photosensitive patterns 21 may be removed using a lift-off operation, thereby forming the first conductive organic layer 30. The organic material may be PVK or PS. The organic material may be mixed with a solvent such as chloroform.

In the embodiment of FIGS. 12 through 18, PVK may be applied on the substrate 10 by using spin coating. The organic material may be applied on the substrate 10 while rotating the substrate 10 at about 1000-3000 rpm. More specifically, the organic material may be dropped onto the substrate 10 while rotating the substrate 10 at about 2000 rpm, and then the substrate 10 may be further rotated for about 50 to 100 seconds so that the organic material can be uniformly applied on the substrate 100. If the rotation speed of the substrate 10 is lower than 2000 rpm, the organic material, which is in a liquid phase, may not be able to be uniformly applied on the substrate 10. On the other hand, if the rotation speed of the substrate 10 is higher than 2000 rpm, the organic material may be thinly deposited near the center of the substrate 10, and thus may not be sufficiently flat. Thereafter, a baking operation is performed on the organic material at a temperature of about 100-150° C. for about 1-10 minutes. Alternatively, the organic material may be applied on the substrate 10, and then the substrate 10 may be rotated so that the organic material can be uniformly distributed.

Thereafter, the first photosensitive film patterns 21 and portions of the organic material on the first photosensitive film patterns 21 are removed by performing a lift-off operation. As a result, the first conductive organic layer 30 is formed. Referring to FIG. 14(b), when the organic material is applied on the substrate 10 by using spin coating, most of the organic material is disposed on a portion of the substrate 10 exposed between the first photosensitive patterns 21, and the remaining organic material is disposed on each of the first photosensitive patterns 21. Thereafter, the first photosensitive film patterns 21 are removed by performing a strip operation. Then, portions of the organic material on the first photosensitive film patterns 21 are removed along with the first photosensitive film patterns 21. As a result, the first conductive organic layer 30 is formed on a portion of the substrate 10 where the first photosensitive film patterns 21 are not formed.

The first conductive organic layer 30 overlaps part of the lower conductive layer 20. Referring to FIG. 14, the first conductive organic layer 30 may be formed as a rectangle, and the lower conductive layer 20 may extend across the middle of the first conductive organic layer 30. However, the present invention is not restricted to this. That is, the first conductive organic layer 30 may be formed as a circle, an ellipse, or a polygon other than a rectangle.

Referring to FIG. 15, a metal layer 40a for forming nanocrystals is formed on the first conductive organic layer 30. The metal layer 40a overlaps part of the overlapping area of the first conductive organic layer 30 and the lower conductive layer 20.

In order to form the metal layer 40a, the substrate 10, on which the first conductive organic layer 30 is formed, is loaded in a chamber for the deposition of a metal. A portion of the first conductive organic layer 30 on which the metal layer 40a is to be formed is exposed by a second shadow mask. More specifically, the second shadow exposes a portion of the first conductive organic layer 30 so that the metal layer 40a can be formed in the overlapping area of the first conductive organic layer 30 and the lower conductive layer 20. The shape of the portion of the first conductive layer 30 exposed by the second shadow mask may be the same as the shape of the first conductive organic layer 30. Thereafter, the metal 40a is formed on the first conductive organic layer 30 by evaporating a metal at a temperature of about 1000 to 1500° C. and at a deposition rate of about 0.01 to 1.0 Å/s while maintaining the pressure in the chamber at a range of about 5×10⁻⁷ to 5×10⁻² Pa. This type of evaporation is referred to as vacuum evaporation.

More specifically, the evaporation of the metal may be performed at a deposition rate of about 0.1-0.5 Å/s. The metal layer 40a may be formed to a thickness of about 1-100 nm, but the present invention is not restricted to this. That is, the metal layer 40a may be formed to a thickness of about 5-40 nm. If the evaporation of the metal is performed at a deposition rate outside the above-mentioned deposition rate range or if the thickness of the metal layer 40a is outside the above-mentioned thickness range, the metal layer 40a may not have a bistable conduction property. The metal layer 40a may be formed of Au, Pt, Ag, Ti, Ni, Cu or an alloy thereof. More specifically, the metal layer 40a may be formed of Au, thereby obtaining nanocrystals that are formed of a pure, non-oxidized metal.

Since the metal layer 40a is formed in a structure constituted by the lower conductive layer 20 and an upper conductive layer 60, it is possible to prevent a short circuit between the metal layer 40a and the lower conductive layer 20 and between the metal layer 40a and the upper conductive layer 60.

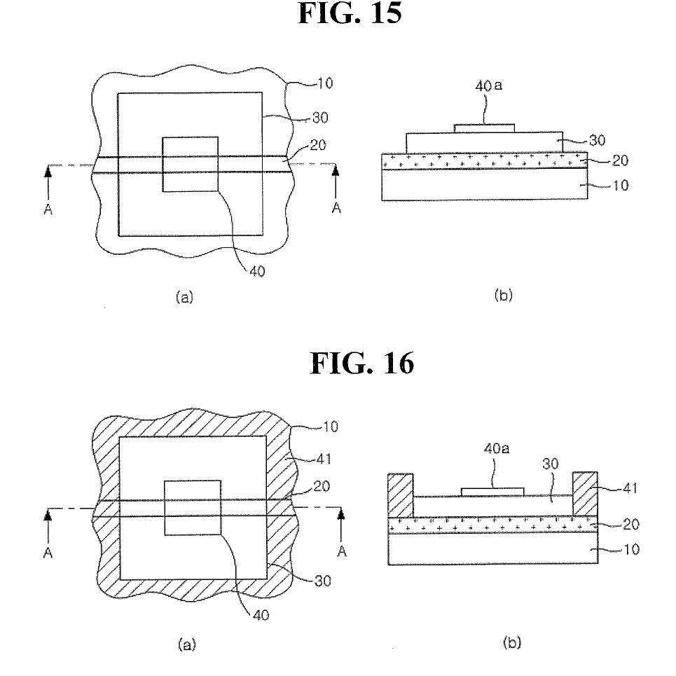

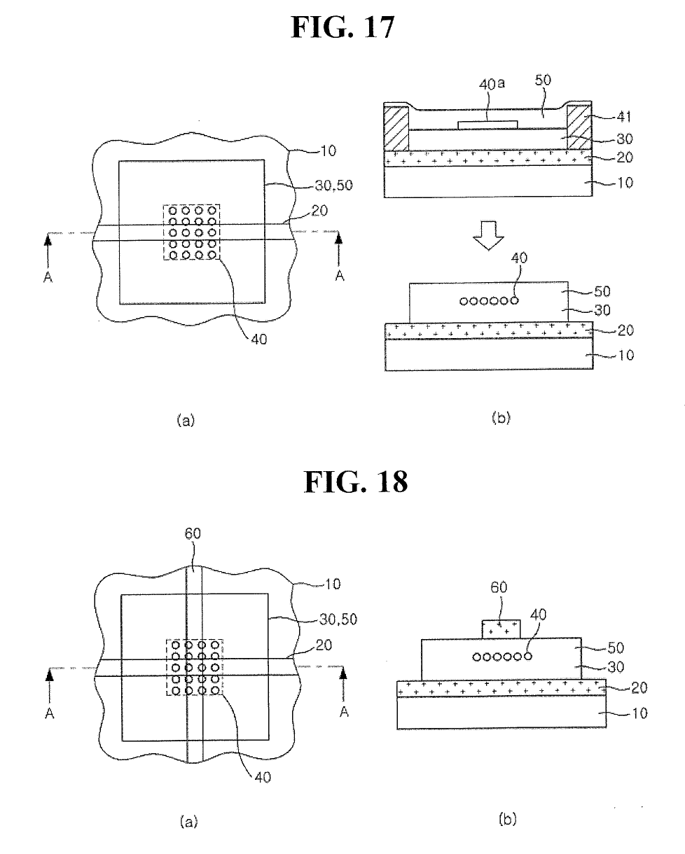

Referring to FIGS. 16 and 17, a second conductive organic layer 50 is formed on the first conductive organic layer 30, on which the metal layer 40a is formed.

The second conductive organic layer 50 may be formed using the same method used to form the first conductive organic layer 30. More specifically, mask patterns 41 that expose a portion of the substrate 10 on which the second conductive organic layer 50 is to be formed is formed on the substrate 10, and the substrate 10 is coated with an organic material by using spin coating. Thereafter, the mask patterns 41 and portions of the organic material on the mask patterns 41 are removed, thereby forming the second conductive organic layer 50, which surrounds the metal layer 40a. A detailed description of the formation of the second conductive organic layer 50 will be omitted.

The second conductive organic material 50 may be formed of PVK. The first and second conductive organic layers 30 and 50 may be formed to a thickness of about 5-100 nm. The second conductive organic layer 50 surrounds the metal layer 40a, which overlaps part of the first conductive organic layer 30. The second conductive organic layer 50 may have the same size as or a smaller size than the first conductive organic layer 30.

Thereafter, a curing operation is performed on the substrate 10. That is, thermal treatment is performed on the substrate 10 at a temperature of about 200-400° C. for about 1-3 hours so that the first and second conductive organic layers 30 and 50 and the metal layer 40a can become dense and activated. During the curing operation, the metal layer 40a is transformed into nanocrystals 40, and this will hereinafter be described in detail. The metal layer 40a, e.g., an Au layer or an Ag layer, has a different surface energy level from that of the first and second conductive organic layers 30 and 50. Therefore, during the curing operation, mass transfer occurs so that the surface energy of each of the first and second conductive organic layers 30 and 50 and the metal layer 40a can decrease. That is, in order to reduce surface energy, the Au layer or the Ag layer may be partially lifted off and agglomerated, thereby forming nanocrystals. However, if the curing operation is performed under processing conditions, other than those set forth herein, the Au layer or the Ag layer may not be able to be properly lifted off and agglomerated.

Referring to FIG. 18, the upper conductive layer 60 is formed on the substrate 10, on which the second conductive organic layer 50 is formed. The upper conductive layer 60 may be formed as a straight line that perpendicularly intersects the lower conductive layer 30.

For this, the substrate 10 may be loaded in a chamber for the deposition of a metal, and a portion of the second conductive organic layer 50 and a portion of the substrate 10 on which the upper conductive layer 60 is to be formed are exposed by a third shadow mask. In this manner, the upper conductive layer 60 can be formed so as to partially overlap the nanocrystals 40. More specifically, the upper conductive layer 60 can be formed so that the nanocrystals 40 can be disposed in the overlapping area of the upper conductive layer 60 and the lower conductive layer 20.

Thereafter, the upper conductive layer 60 is formed on the exposed portion of the second conductive organic layer 50 and the exposed portion of the substrate 10 of the substrate 10 by evaporating a metal at a temperature of about 1000 to 1500° C. and at a deposition rate of about 1 to 10 Å/s while maintaining the pressure in the chamber at a range of about 5×10⁻⁷ to 5×10⁻⁵ Pa. The upper conductive layer 60 may be formed of Al to a thickness of about 60-100 nm. The lower conductive layer 20 may be formed as a vertical straight line. Then, it is possible to provide a nonvolatile memory device that has 4 F² memory cells and can thus provide high integration density. A rinsing operation may be performed before or after the deposition of the lower conductive layer 20 on the substrate 10. 4 F² memory cells are memory cells having a size of 4 F² where F indicates the line width of a memory device.

Thereafter, a metal interconnection operation may be performed in order to connect each of the upper conductive layer 60 and the lower conductive layer 20 to an external electrode. In addition, a passivation operation for protecting a memory device may be performed. In the embodiment of FIGS. 12 through 18, the first and second conductive organic layers 30 and 50 are formed of PVK. Thus, it is possible to prevent the properties of the first and second conductive organic layers 30 and 50 from being altered during a passivation operation, which involves performing thermal treatment at a high temperature of about 300° C.

The present invention, however, is not restricted to the embodiment of FIGS. 12 through 18. The lower and upper conductive layers 20 and 60, the first and second conductive organic layers 30 and 50, and the nanocrystals 40 may be formed using various methods, other than thermal evaporation. For example, the lower and upper conductive layers 20 and 60, the first and second conductive organic layers 30 and 50, and the nanocrystals 40 may be formed using electron-beam (E-beam) deposition, sputtering, chemical vapor deposition (CVD) or atomic-layer deposition (ALD). The lower and upper conductive layers 20 and 60 and the first and second conductive organic layers 30 and 50 may be formed through patterning. That is, each of the lower and upper conductive layers 20 and 60 and the first and second conductive organic layers 30 and 50 may be formed by depositing a conductive material on the substrate 10 and performing an etching operation on the conductive material.

In the embodiment of FIGS. 12 through 18, the first and second conductive organic layers 30 and 50 may be formed of PVK, and the nanocrystals 40 may be formed of Au or Ag. In this manner, it may be possible to provide Au or Ag nanocrystals.

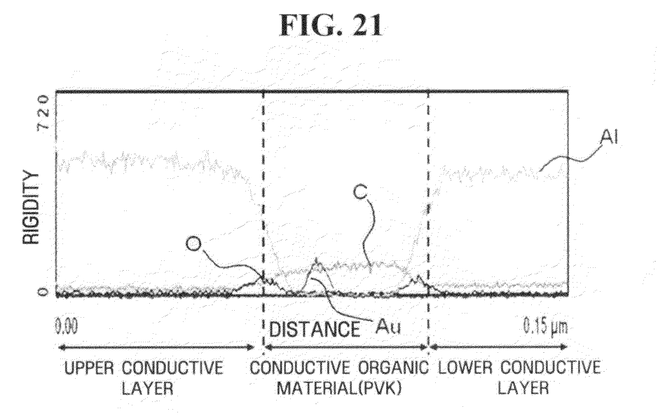

FIG. 19 shows a TEM image of a memory device obtained by the method of the embodiment of FIGS. 12 through 18, FIGS. 20A through 20D illustrate energy dispersive spectroscopy (EDS) images of the distributions of various components of the memory device illustrated in FIG. 19, and FIG. 21 illustrates a graph of the physical properties of the memory device illustrated in FIG. 19.

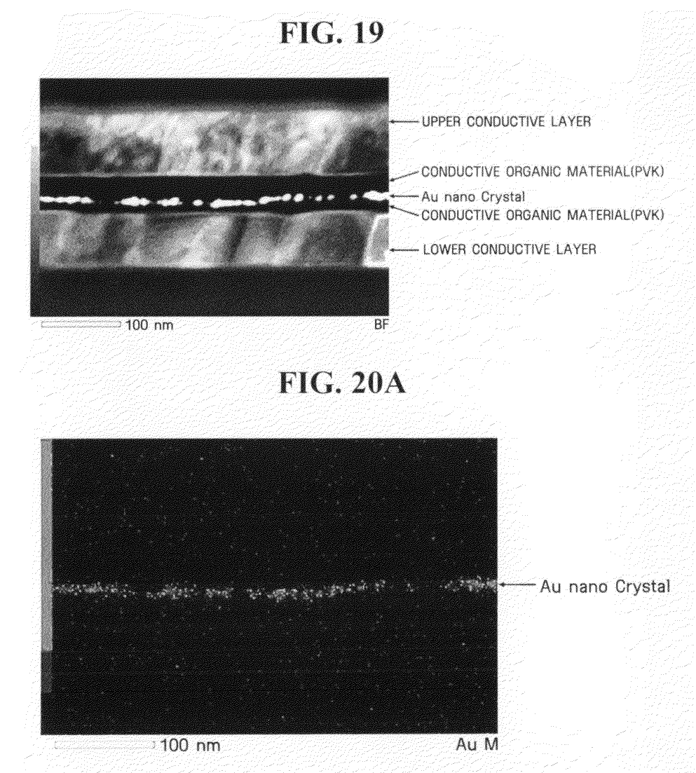

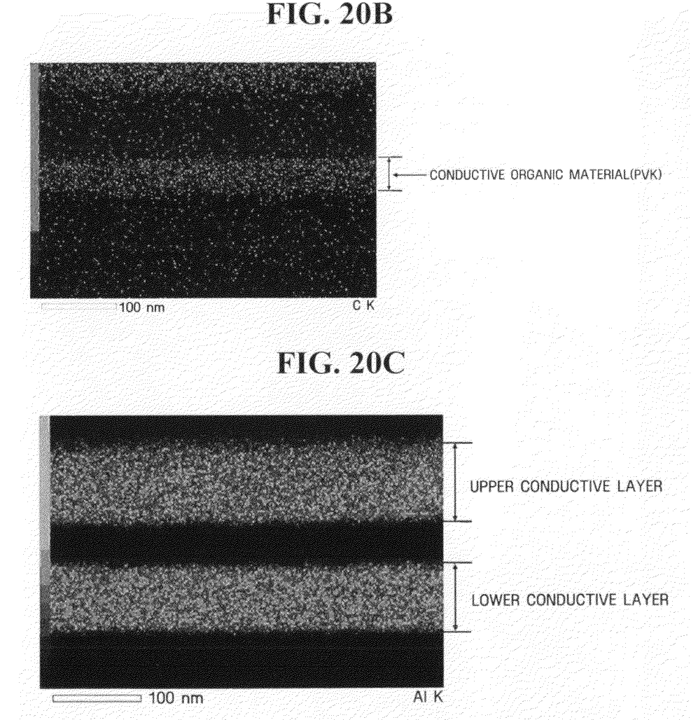

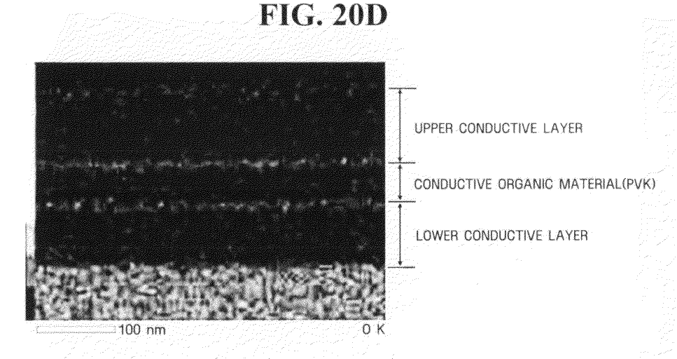

Referring to FIG. 19, upper and lower organic conductive layers are interposed between upper and lower conductive layers, and nanocrystals are interposed between the upper and lower conductive organic layers. FIG. 20A illustrates the distribution of Au, FIG. 20B illustrates the distribution of carbon (C), which is one of the main components of a conductive polymer, FIG. 20C illustrates the distribution of Al, and FIG. 20D illustrates the distribution of oxygen (O).

Referring to FIGS. 19 through 20D, Al, which is the material of upper and lower conductive layers, is distributed on the top and the bottom of a conductive organic layer, and Au, which is the material of nanocrystals, is distributed in the conductive organic layer. Oxygen (O) does not overlap Au, and is distributed among the conductive organic layer and the upper and lower conductive layers. Referring to FIG. 21, a horizontal axis represents the depth in the memory device illustrated in FIG. 19, and a vertical axis represents rigidity. Referring to FIG. 21, a C-based conductive organic layer is disposed between Al-based conductive layers, and an Au nanocrystals is disposed in the C-based conductive organic layer. Oxygen (O) is distributed among the C-based conductive organic layer and the Al-based conductive layers. Since no oxygen is distributed in the Au nanocrystals, the Au nanocrystals does not oxidize.

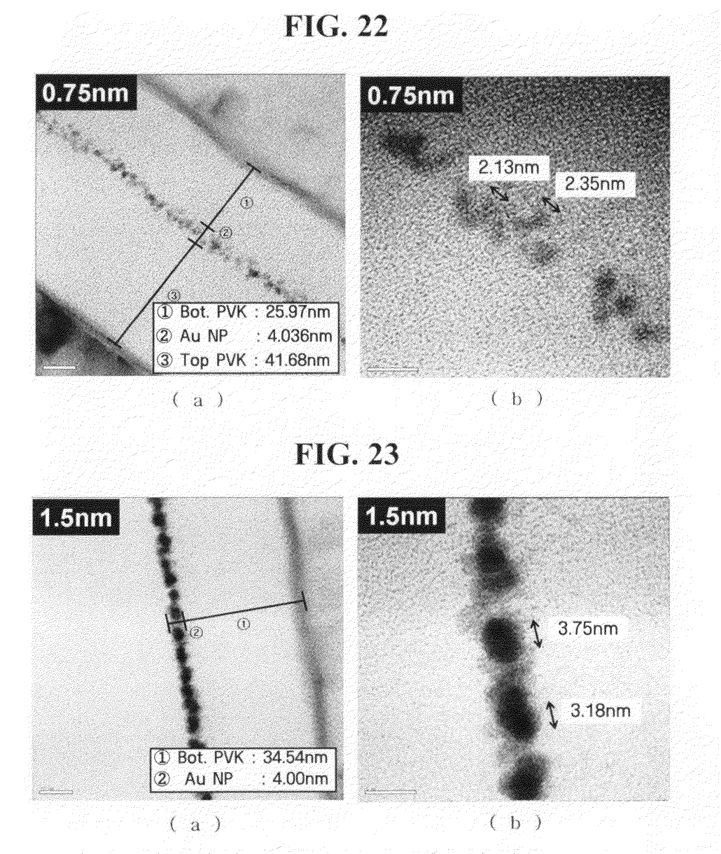

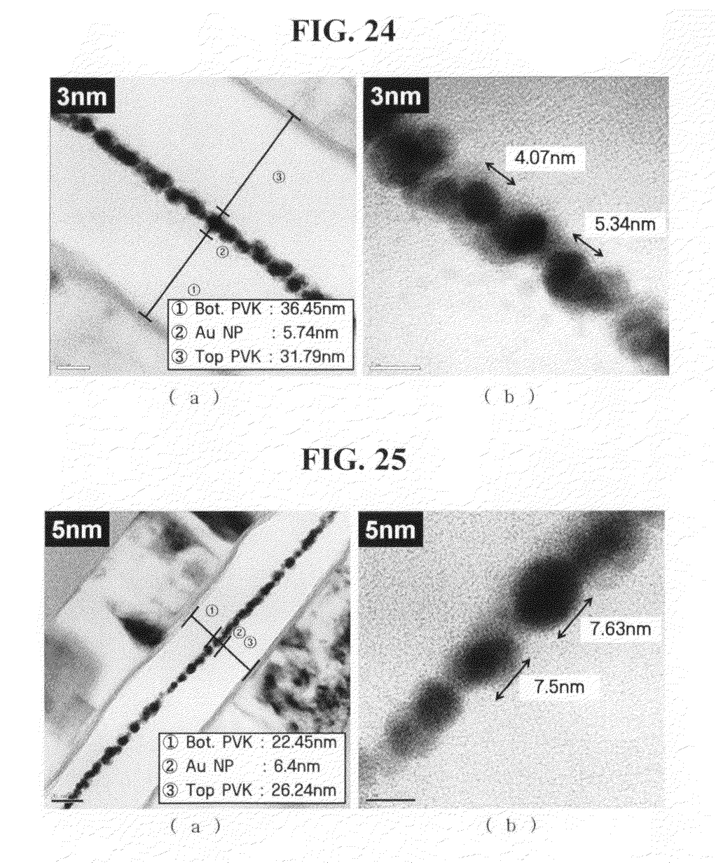

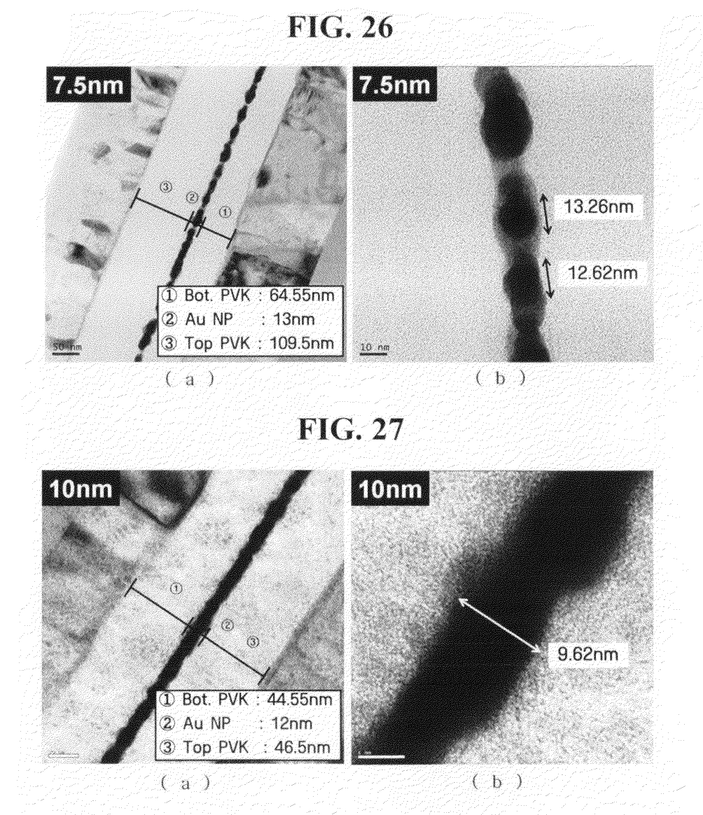

By using the embodiment of FIGS. 12 through 18, it is possible to manufacture Au nanocrystals of various sizes, and this will hereinafter be described in detail with reference to FIGS. 22 through 27.

FIGS. 22 through 27 illustrate TEM images of Au nanocrystals of various sizes obtained by the method of the embodiment of FIGS. 12 through 18. Referring to FIGS. 22 through 27, it is possible to form Au nanocrystals of various sizes by varying the thickness of the deposition of Au. The properties and the performance of a memory device may be altered by adjusting the size of Au nanocrystals. However, if the thickness of the deposition of Au exceeds 10 nm, no Au nanocrystals may be performed under the processing conditions set forth herein.

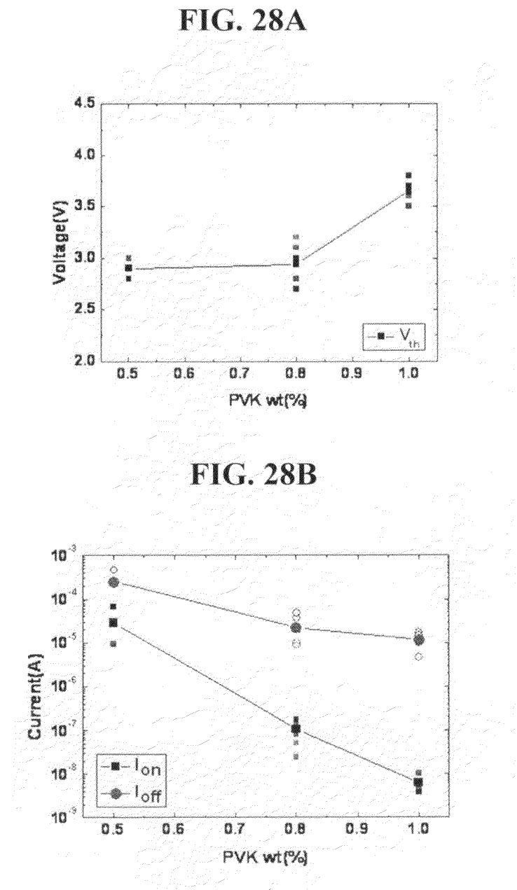

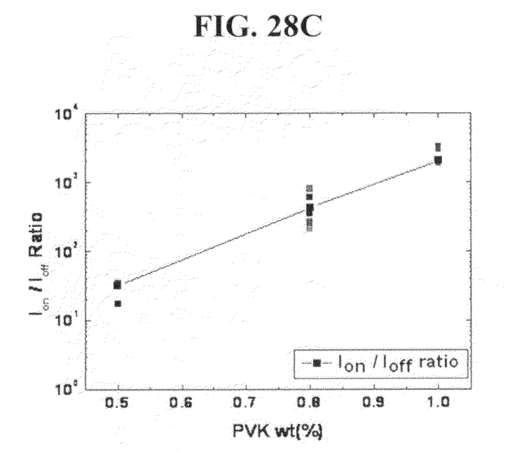

By using the embodiment of FIGS. 12 through 18, it is possible to manufacture various memory devices and/or adjust the properties and the performance of a memory device by varying the concentration of a conductive organic material, and this will hereinafter be described in detail with reference to FIGS. 28A through 28C.

FIGS. 28A through 28C illustrate graphs of the current-voltage properties of memory devices having different conductive organic material concentrations. Referring to FIGS. 28A and 28B, as the concentration of a conductive organic material increases, a threshold voltage Vₜₕ) increases, and a logic-high current Iₒₙ and a logic-low current I_{off} both decrease. In addition, referring to FIG. 28C, as the concentration of a conductive organic material increases, the ratio of the logic-high current Iₒₙ and the logic-low current I_{off} increases.

As described above, according to the present invention, it is possible to provide a highly-integrated memory device that consumes less power due to having conductive organic layers and nanocrystals between the conductive organic layers, provides high operating speed and has 4 F² memory cells.

According to the present invention, it is possible to repeatedly perform read, write and erase operations with the use of the bistable conduction property of a conductive organic material and to maintain data present in each memory cell of a memory device even when the memory device is powered off.

According to the present invention, it is possible to realize an MLC memory device by using the bistable conduction property of a conductive organic material.

According to the present invention, it is possible to provide the thermal stability of a memory device by using a conductive organic polymer.

According to the present invention, it is possible to reduce the time required to deposit a conductive organic layer by forming a conductive layer using spin coating.

According to the present invention, it is possible to form a conductive organic layer in various shapes by using mask patterns that can be formed on a substrate in various shapes.

According to the present invention, it is possible to adjust the properties of a memory device and improve the performance of a memory device by adjusting the size of Au nanocrystals.

According to the present invention, it is possible to adjust the properties of a memory device and improve the performance of a memory device by adjusting the concentration of a conductive organic material.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a nonvolatile memory device, the method comprising:
forming a lower conductive layer on a substrate;
forming a first conductive organic layer on the substrate using spin coating;
forming a metal layer for forming nanocrystals on the first conductive organic layer, the metal layer partially overlapping the first conductive organic layer;
forming a second conductive organic layer on the first conductive organic layer using spin coating;
transforming the metal layer into nanocrystals by curing; and
forming an upper conductive layer on the second conductive organic layer, the upper conductive layer partially overlapping the nanocrystals.

2. The method of claim 1, wherein the use of spin coating comprises:
forming mask patterns on the substrate;
forming an organic material on the substrate using spin coating; and
removing the mask patterns and portions of the organic material on the mask patterns.

3. The method of claim 2, wherein the forming the organic material comprises using poly-N-vinylcarbazole (PVK) or polystyrene (PS) mixed in a solvent.

4. The method of claim 2, wherein the forming the mask patterns comprises:
forming a photosensitive film on the substrate;
performing a lithography operation on the photosensitive film; and
performing an etching operation on the photosensitive film

5. The method of claim 4, wherein the forming the mask patterns further comprises performing a baking operation on the photosensitive film at a temperature of about 100-150° C. for about 1-10 minutes, after the forming the photosensitive film.

6. The method of claim 2, wherein the forming the organic material comprises applying a liquid-phase conductive organic material on the substrate while rotating the substrate at about 1000-3000 rpm.

7. The method of claim 2, wherein the forming the organic material comprises applying a liquid-phase conductive organic material on the substrate and then rotating the substrate at about 1000-3000 rpm.

8. The method of claim 1, wherein the curing comprises performing curing at a temperature of about 200-400° C. for about 1-3 hours.

9. The method of claim 1, wherein the forming the metal layer comprises depositing at least one of Au, Pt, Ag, Ti, Ni, Cu and an alloy thereof using vacuum evaporation.

10. The method of claim 9, wherein the depositing comprises depositing the at least one of Au, Pt, Ag, Ti, Ni, Cu and an alloy thereof at a deposition rate of about 0.01-1.0 Å/s.
